(19) United States
(12) Patent Application Publication
(10) Pub. No.: US 2015/0209707 A1
(43) Pub. Date: Jul. 30, 2015

(54) Active Filter Technology for Photoresist Dispense System

(71) Applicant: Tokyo Electron Limited, Tokyo (JP)

(72) Inventor: Anton J. deVilliers, Clifton Park, NY (US)

(21) Appl. No.: 14/606,273

(22) Filed: Jan. 27, 2015

Related U.S. Application Data
(60) Provisional application No. 61/932,075, filed on Jan. 27, 2014.

(51) Int. Cl. B01D 35/06; G03F 7/26

(52) U.S. Cl. CPC B01D 35/06; G03F 7/26

(57) ABSTRACT

Disclosed herein are systems and methods for filtering photoresist liquids that may be dispensed into a process chamber used to manufacture semiconductor devices. The system may include one or more active filter devices that distribute electrical or mechanical energy into a fluid conduit. The energy may be used to remove particles or molecules based on their size, weight, ionic charge, molecular weight, or a combination thereof. The energy sources may include, but are not limited to, electromagnetic, acoustic, pneumatic, and/or mechanical vibration sources.

### BACKGROUND OF THE INVENTION

Micro-bubbles and small particles in leading-edge photoresist materials create a challenge to the demanding yield requirements of today's shrinking circuit designs. When micro-bubbles are dispensed onto a wafer surface, they can act as an additional lens in the exposure path, ultimately distorting the pattern and affecting yield. Micro-bubbles can also fall on a wafer during the spin-on process and cause etch pits. Proper filter selection, filter priming, and dispense settings chosen during process startup are critical to reducing micro-bubbles. Defect control is extremely critical and continues to be one of the biggest challenges in the lithography process for integrated device manufacturers, as the critical dimension shrinks. Particle removal filters are used in almost every step where a liquid comes in contact with a wafer; hence, it is important to understand the behavior of micro-bubbles and small particles and to reduce the generation of the micro-bubbles and small particles. In general, micro-bubbles are not easily removed from high-viscosity photo-chemicals or surfactinated aqueous photo-chemicals. Removal of these micro-bubbles and/or small particles results in large amount of chemical consumption and long tool down time. Hence, implementation of a system or method that remove micro-bubbles using existing filters can effectively improve the cleanliness of the liquid by reducing the total fraction of micro-bubbles in the fluid flow startup process.

### BRIEF DESCRIPTION OF THE DRAWINGS

The advantages of the technology described above, together with further advantages, may be better understood by referring to the following description taken in conjunction with the accompanying drawings. In the drawings, like reference characters generally refer to the same parts throughout the different views. The drawings are not necessarily to scale, emphasis instead generally being placed upon illustrating the principles of the technology.

FIG. 1 illustrates a representative embodiment for fluid dispensing system using an active filter device to filter to the fluid prior to dispensing.

FIG. 2 illustrates a representative embodiment of an active filter device that uses mechanical energy to remove elements from the fluid prior to dispensing the fluid into a process chamber.

FIG. 3 illustrates a representative embodiment of an active filter device that uses electromagnetic energy to remove elements from the fluid prior to dispensing the fluid into a process chamber.

FIG. 4 illustrates a representative embodiment of an active filter device that uses acoustic energy to remove elements from the fluid prior to dispensing the fluid into a process chamber.

FIG. 5 illustrates a representative embodiment of an active filter device that uses chemical potential differences to remove elements from the fluid prior to dispensing the fluid into a process chamber.

FIG. 6 illustrates a representative embodiment of an active filter device that uses pneumatic energy to remove elements from the fluid prior to dispensing the fluid into a process chamber.

FIG. 7 illustrates a representative embodiment of a filtering system theat incorporates two or more active filter devices to remove elements from the fluid prior to dispensing the fluid into a process chamber.

FIG. 8 illustrates a flow diagram for methods of removing elements from a fluid using one or more active filter devices.

### SUMMARY

Defect control is an important component of for any manufactured product. Controlling defects within chemical manufacturing processes may rely on the cleanliness or purity of the incoming chemicals. Although chemical suppliers provide high quality chemicals to their customers, generally, chemical delivery from the chemical source to point of use may generate particles, micro-bubbles, or chemically alter the fluid that may result in higher manufacturing defects. Within the semiconductor industry, shrinking critical dimensions drives defect control to smaller sizes and uncovers new defect sources that have gone unnoticed in the past. One approach to address this problem may be to improve point of use filter systems to segregate or dissolve the particles, micro-bubbles, or undesirable molecules. Broadly, incoming chemicals may be treated with one or more energy sources to remove or dissolve particles based, at least in part, on the physical and/or chemical characteristics of the particles. These active filters may include one or more energy generating components that may be tuned to remove, alter, and/or dissolve particles. Active filters may replace or augment static filters (e.g., mesh filters) that may remove larger particles prior to reaching the active filter. The energy components may generate any type of energy that may be characterized or quantified by amplitude, frequency, and/or temperature. The active filter energy sources may one or more of the following types of energy: vibration, electromagnetic, acoustic, pneumatic and/or chemical potential.

The active filter or fluid treatment device may include an inlet to receive the fluid and an outlet to provide the fluid to a fluid dispenser. Within the fluid treatment device, a fluid conduit may transport the fluid between the inlet and outlet and an energy distribution component may be proximate to the fluid conduit. The fluid conduit may be a boundary surface that contains the fluid and directs the fluid from the fluid source to the point of use (e.g., dispensing device). The energy distribution component may generate one or more forms of energy that may remove particles from the fluid, reduce the size of the particles, and/or dissolve the particles into the fluid.

In one embodiment, the fluid treatment device may include a mechanical device that may generate vibrations that are directed toward the fluid conduit. The vibrations may be tuned to a resonance frequency of one or more particle types that may break the particles into smaller pieces or that may dissolve the particles (e.g., micro-bubbles) into the fluid. The mechanical device may include a vibration device that may oscillate between two different positions or rotate an unbalanced object to generate vibrations at one or more frequencies. The frequency of the vibrations may depend on the resonance frequency of particles within the fluid.

In another embodiment, the fluid treatment device may include an acoustic device that provides acoustic (e.g., ultrasound) energy to the fluid conduit. In one specific embodiment, the acoustic energy may include a frequency above 350 kHz or below 80 kHz.

In another embodiment, the active filter may be incorporated into a semiconductor processing tool that may dispense fluids (e.g., photoresist) onto a substrate. The fluid conduit between the fluid source and a process chamber may also include a compaction filter and/or an absorption filter that filters the fluid in combination with one or more active filters.

In one embodiment, the fluid may be provided from a chemical source to a dispensing element incorporated into a chemical processing tool. The fluid may include a portion of atoms (e.g., monatomic elements) or a portion of objects (e.g., molecules that may be inorganic, organic, metallic, micro-bubbles, or a combination thereof) that may cause defects on the substrate. The fluid conduit may be integrated with one or more energy components that apply mechanical or electrical energy to the fluid to remove and/or dissolve the atoms or objects in the fluid. The atoms objects may be removed from the fluid and the objects may be broken down into smaller objects and/or decreasing their size by altering their chemical structure. In certain embodiments, the objects may include micro-bubbles that may be dissolved into the fluid.

### DETAILED DESCRIPTION

Although the present invention will be described with reference to the embodiments shown in the drawings, it should be understood that the present invention can be embodied in many alternate forms of embodiments. In addition, any suitable size, shape or type of elements or materials could be used.

A fluid filter system may use meshed material or other flow obstruction components to remove certain size objects (e.g., particulates) from the fluid. The mesh may impede fluid flow and cause turbulent flow within that may create a dead space of gas or micro-bubbles that reduces the efficiency and/or performance of the filter. Flow obstruction components may not be able to remove small particles due to mesh material dimensions or pressure drop limitations that may limit the flow rate or generate more particles or micro-bubbles.

Fluid micro-bubbles or undesirable objects, in a filter, may be removed by applying energy to the filter to reintroduce the object's vapor back into the liquid phase of the fluid or to move the objects through the filter at a higher rate. Micro-bubbles or objects may be less than one millimeter (mm) in diameter and may be dissolved into the surrounding fluid due to their unstable nature. As a result, relatively small amounts of applied energy may be applied to dissolve the micro-bubbles/objects or to move the micro-bubbles/objects in a way that causes their dissolution. The energy sources may be used to reduce dead space of micro-bubbles by preventing the concentration of dead space of moving the micro-bubbles/objects away from the path of liquid flow or to an area the impact of the micro-bubbles may be mitigated or removed from the liquid. The filter may operate under a variety of processing conditions that may include varying amounts of micro-bubbles/objects in the fluid or gas trapped in the filter.

Particles or undesirable objects may be introduced by the chemical delivery system by the components of the system or by the pressure or temperature changes within the fluid conduit. The objects may include, but are not limited to, organic, inorganic, metallic, or combination thereof that may be in molecular or atomic form. The objects may include molecules or atoms that may be unrelated to liquid and are introduced into the fluid conduit in some manner. The objects may be removed from the liquid or altered, physically or chemically, within the liquid to minimize defects caused by the fluid dispense process. One approach to removing or altering the objects may be to apply various types of energy (e.g., mechanical, acoustic, electrical, chemical, or pneumatic) to the fluid conduit that may influence or impact the objects based on the mechanical, electrical, or chemical characteristics of the objects. The objects may be targeted for treatment based on their size, weight, ionic charge, molecular weight, or a combination thereof. For example, the applied energy may be used to remove the objects from the fluid flow so that they do not reach the process chamber, alter the structure or composition of the object to a smaller size, or alter the chemical composition of the object to minimize undesirable chemical reactions within the fluid conduit or the process chamber.

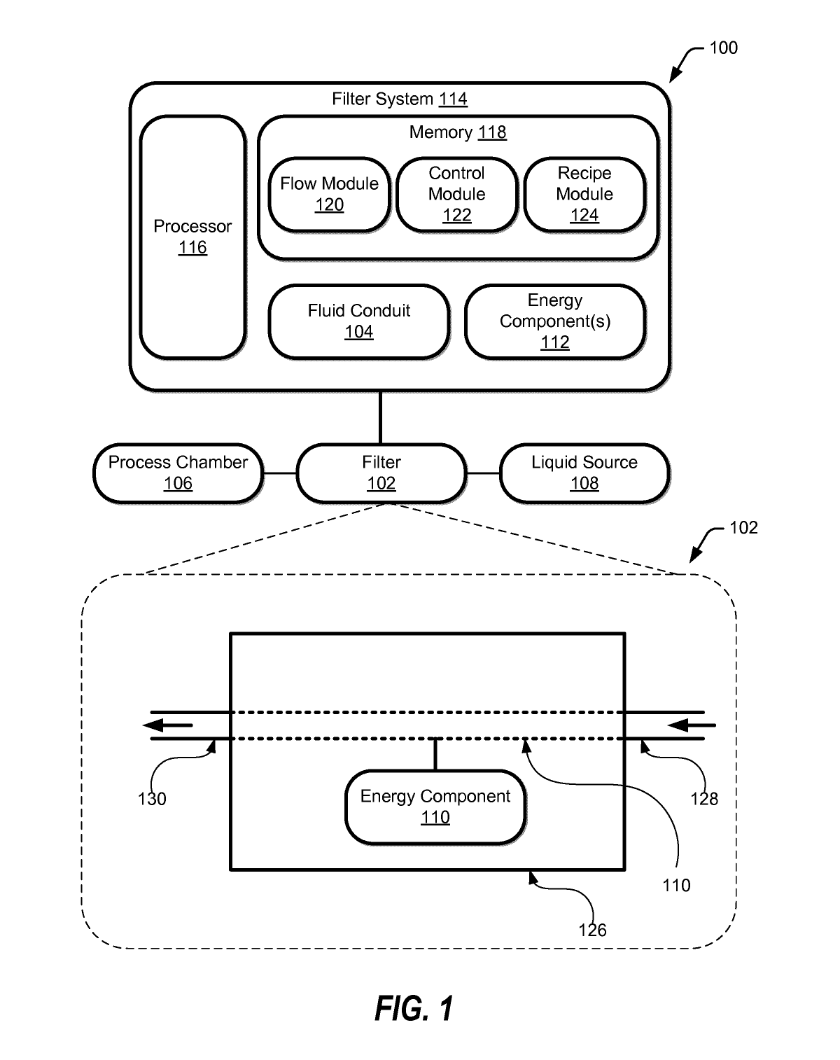

FIG. 1 illustrates a representative embodiment for a fluid dispensing system 100 using an active filter device or filter 102 to treat fluid passed along a fluid conduit 104 between a process chamber 106 and a liquid source 108. The fluid conduit 104 may include a boundary surface 110 that contains and/or directs the fluid flow between the liquid source 104 and the process chamber 106. The filter 102 may be applied to any portion of the fluid conduit 104 that may include a variety of components that may control the fluid flow. The filter 102 may include one or more embodiments energy components 112 to treat the fluid within the fluid conduit 104. The energy components 112 may reduce the amount of time and liquid materials used during filter start-up or refresh procedures. The energy components 112 may also maintain filter efficiency during continuous operation or increase the time between maintenance periods. Using the energy components 112 for active filtering sources may reduce consumable cost, labor cost, or yield cost from defects on the substrate that receives the fluid.

Many types of energy may be applied to the filter housing 126, filter inlet 128, filter outlet 130, and/or the fluid conduit 104 to move, alter or dissolve the objects (e.g., micro-bubbles) such as, but not limited to, vibration, microwave, thermal, pneumatic, or ultrasound. The magnitude of the energy may vary depending on the application or use of the filter 102. For example, filter 102 use may be classified into different operational modes that determine the energy magnitude or even the type of energy used to move, alter or dissolve the objects (e.g., micro-bubbles, dead space, particle, atoms, molecules, etc.). The operational modes may include, but are not limited to start-up or filter wetting, continuous operation, and refresh or post-maintenance. The energy modes may be classified as low, medium, and high, whereas low energy may be used during continuous operations, medium energy for start-up, and high energy for refresh. The energy may include any energy source that may influence the movement, concentration, or size of the objects. Two or more energy sources may be used in conjunction with one another to enhance energy uniformity across the filter or to increase the amount of energy via superposition.

The principle of superposition describes the overlapping of waves (e.g., energy waves) to create a net impact that is higher than the individual waves themselves. For example, the intersection or overlap of two more waves may result in a net impact on the magnitude of the waves at or the near the intersection. In other instances, the net impact may be lower if the magnitudes of the waves are opposing each other. This may occur when intersecting waves are out of phase with each other may dampen the effect of the waves. In one embodiment, multiple energy components 112 may be applied to the filter to apply energy more uniformly or to increase the applied energy via the principle of superposition. The type and placement of the energy components 112 may be based on, but is not limited to, filter geometry, filter materials, filter operating conditions, filter working fluids, and/or filter orientation.

In one specific embodiment, the energy components may be coupled to or incorporated into filters 102 used in liquid dispensing systems 100 that apply measured amounts of fluid on to substrates. The filters may be used to remove particulates from the fluid to avoid dispensing the particulates on the substrate. The filters 102 may have a life cycle that ranges from installation, operational use, and maintenance recovery. The energy components 112 may be used through the life cycle of the filter 102 or for specific intervals of the life cycle and may be operated at different conditions during different life cycle events. The life cycle events may be classified as low, medium, or high energy applications.

The low energy applications may be used during the continuous operation phase of the life cycle which may include, but are not limited to, operating conditions used during repetitive use of the filter 102 under the same or similar process conditions over a period of time. The low energy applications may be used during steady state conditions, in which the amount of objects is expected to be at a relatively low value. In one specific embodiment, the low energy applications may be measure in gravitational force for vibration energy components 112. The process range may be 3 g to 8 g. Other energy components 112 may emit a similar amount of energy but using different emission mechanisms and different energy settings (e.g., frequency, amplitude, temperature, etc.).

The medium energy applications may be used during the start-up phase of the life cycle, in which a new filter 102 is installed and may not have been used during production. A characteristic of this life cycle is relatively larger amount of objects compared to the low energy application. The filter 102 may be dry and dead space (e.g., gas or air) that may have to be removed by flowing liquid into the filter. In one specific embodiment, the medium energy applications may be measured in gravitational force for vibration energy components. The process range may be 10 g to 14 g. Other energy sources may emit a similar amount of energy but using different emission mechanisms and different energy settings (e.g., frequency, amplitude, temperature, etc.).

The high energy applications may be used during the refresh phase of the life cycle which may include, but is not limited to, post maintenance activity on the filter 102, the liquid distribution system 100, or the tool that includes the liquid distribution system 100. A characteristic of this life cycle may be a higher density of objects within the filter than during the other life cycle phases. The higher density may cause a relatively higher degree of objects that may need a relatively higher level of energy that was used in the other applications. In one specific embodiment, the medium energy applications may be measure in gravitational force for vibration energy components. The process range may be 14 g to 25 g. Other energy sources may emit a similar amount of energy but using different emission mechanisms and different energy settings (e.g., frequency, amplitude, temperature, etc.).

The liquid distribution system 100 may also include a filter system 114 that may include hardware, firmware, software, or a combination thereof to control the energy components 112, monitor conditions in the fluid conduit 104, the liquid source 108, the process chamber 106, or any other component that may be related to the operation of the process tool or its supporting equipment. In FIG. 1, the filter system 114 may include the illustrated components, however they represent one embodiment and the scope of the claims are not intended to be limited to this embodiment. A person or ordinary skill in the art could implement the capabilities, features, modules, and/or components in a variety of ways using different embodiment of hardware, firmware, software, or a combination thereof.

Turning to FIG. 1, the filter system 114 may include a computer processor 116 that may integrated with memory 118 that includes non-transitory tangible computer readable storage media that may store computer-executable instructions that, when executed by the computer processor 114, may perform one or more tasks to treat or filter the fluid in the fluid conduit 104. The filter system 114 may control the amount and/or type of energy that may be generated by one or more energy components 112. The filter system 114 may interface with the sensors (not shown) and control elements (not shown) that monitor and/or control the fluid conduit 104, the process chamber 106 and/or the liquid source 108.

In one embodiment, the filter system 114 may monitor and/or control one or more operations and process conditions that may be used to deliver fluid from the liquid source 108 to the process chamber 106. By way of example, and not limitation, the filter system 114 may include a flow module 120 to monitor the process conditions within or proximate to the fluid conduit 104. In conjunction with a control module 122, the filter system 114 may control any component that may influence the process conditions within the fluid conduit 104, the process conditions may include, but are not limited to, pressure, temperature, energy (e.g., energy components 112), or combination thereof. The control module 122 may also implement open loop or closed loop control of one or more process conditions in the fluid conduit 104. The filter system 114 may also include a recipe module 124 that may include computer-executable instructions or programmable logic that may implement the process condition settings for specific functions related to continuous operation and/or maintenance operations of the filter 102 or fluid conduit 104.

In the FIG. 1 embodiment, the computer processor 116 may include one or more processing cores and are configured to access and execute (at least in part) computer-readable instructions stored in the one or more memories. The one or more computer processors 116 may include, without limitation: a central processing unit (CPU), a digital signal processor (DSP), a reduced instruction set computer (RISC), a complex instruction set computer (CISC), a microprocessor, a microcontroller, a field programmable gate array (FPGA), or any combination thereof. The computer processor 116 may also include a chipset(s) (not shown) for controlling communications between the components of the filter system 114. In certain embodiments, the computer processors 116 may be based on Intel® architecture or ARM® architecture and the processor(s) and chipset may be from a family of Intel® processors and chipsets. The one or more computer processors may also include one or more application-specific integrated circuits (ASICs) or application-specific standard products (ASSPs) for handling specific data processing functions or tasks.

The memory 118 may include one or more tangible non-transitory computer-readable storage media (“CRSM”). In some embodiments, the one or more memories may include non-transitory media such as random access memory (“RAM”), flash RAM, magnetic media, optical media, solid state media, and so forth. The one or more memories may be volatile (in that information is retained while providing power) or non-volatile (in that information is retained without providing power). Additional embodiments may also be provided as a computer program product including a non-transitory machine-readable signal (in compressed or uncompressed form). Examples of machine-readable signals include, but are not limited to, signals carried by the Internet or other networks. For example, distribution of software via the Internet may include a non-transitory machine-readable signal. Additionally, the memory may store an operating system that includes a plurality of computer-executable instructions that may be implemented by the computer processor 116 to perform a variety of tasks to operate the filter system 114.

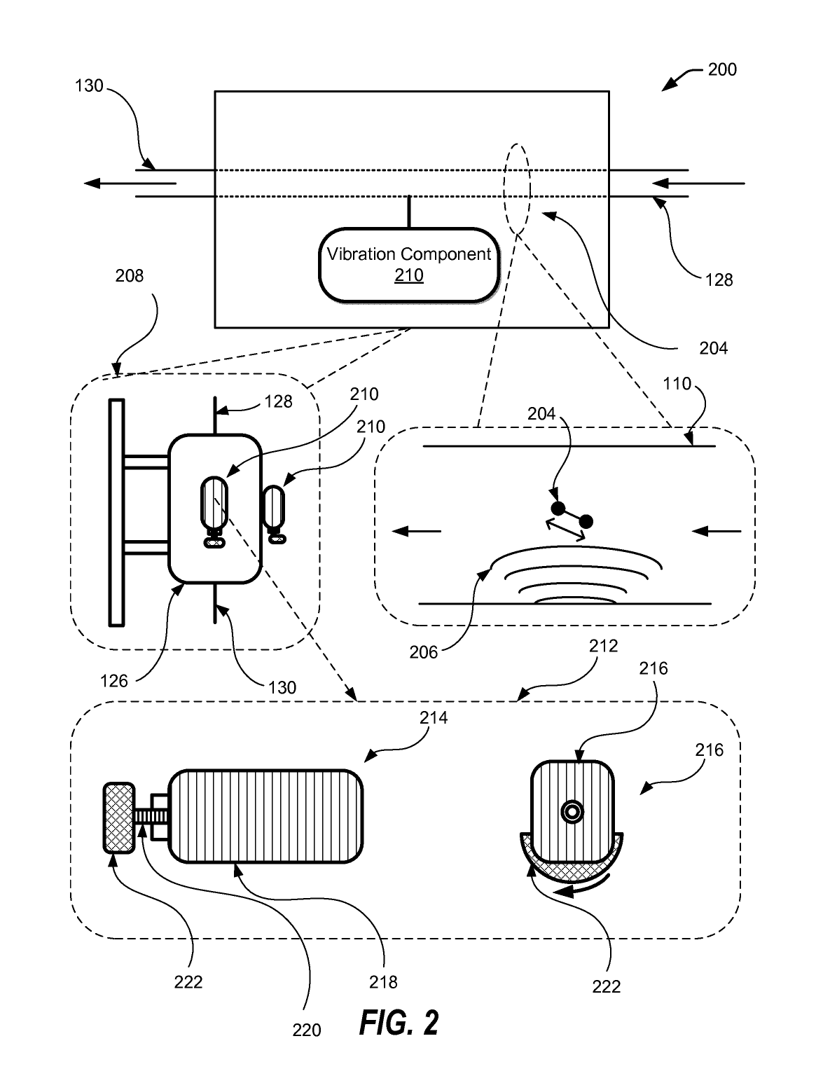

FIG. 2 illustrates a representative embodiment of a vibration filter system 200 that uses mechanical energy to remove or alter objects in the fluid prior to dispensing the fluid into a process chamber 106. FIG. 2 also includes a detailed illustration 202 of objects 204 in the fluid conduit 104 and the representation of mechanical energy 206 used to treat the objects. Another detailed illustration 208 depicts one embodiment of the vibration components 210 attached to the filter housing 126 along with a detailed illustration 212 of one embodiment of the vibration component 210.

Mechanical energy sources may be used to purge or dissolve micro-bubbles, gas (e.g., air, vapor), or any other object 204 (e.g., molecule, atom) that may be impacting the performance of the filter conduit 104. The micro-bubbles or objects may adhere to the filter mesh (not shown) or the filter wall and the mechanical energy sources may be optimized to remove them on an as-needed basis or continuous basis. The continuous energy application may remove micro-bubbles or objects 204 generated by the normal fluid flow and may prevent micro-bubbles from becoming nucleation sites that generate larger bubbles. The mechanical energy source may also prevent objects 204 from becoming nucleation sites by altering their structure or composition to make them smaller in size and/or to prevent the combination of atom and/or molecules from forming larger objects (not shown). In other embodiments, during non-manufacturing activity a high amount of energy may be used to dissolve higher concentrations of micro-bubbles or larger dead spaces that may during continuous processing. The higher amount of energy may be used to condition the filter to enable the filter to operate in continuous operation.

In the FIG. 2 embodiment, the mechanical energy source may include, but is not limited to, a vibration component 210 that generates vibrations (e.g., mechanical energy 206) that are propagated into the fluid conduit 104. As noted in the description of FIG. 1, the vibrations may be tuned to one or more frequencies to target particular types of objects 204. Certain objects may have a particular resonance frequency that may enable the mechanical energy to break apart the objects, as shown in FIG. 2, or to prevent the combination, nucleation, and/or agglomeration of one or more objects within the fluid. One or more vibration components 210 may be coupled to the filter 102 shown in illustration 208. The vibration components 210 may be arranged to complement each other using the principles of superposition. In one specific embodiment (e.g., illustration 208), the vibrations components 210 may be arranged at 90° angles from each other around the filter conduit 114.

In another embodiment, the vibration components 210 or energy components 110 may be aligned along the fluid conduit 104, such that each of the vibration components 210 may be tuned to a different frequency and/or amplitude to target different types of objects 204 at different positions along the fluid conduit 204. For example, the initial vibration component 210 may target larger objects 204 and successive vibration components 210 may target smaller and smaller or different types (e.g., different molecules and/or atoms) of objects along the fluid conduit 104.

In one embodiment, the vibration components 210 may emit vibration energy 206 at various g-force levels up to approximately 30 g. The g-force levels may be generated by the vibration components 210 shown in illustration 212 that includes a top view 214 and a back view 216 of the vibration component 210. The vibration component 210 may include a rotation motor 218 that has rotates a shaft 220 that may be coupled to an off center mass 222 that is rotated by the shaft 220 to generate the mechanical energy 206. High speed rotation of the off center mass 222 will generate vibrations, periodic or non-periodic, that may be transmitted from the motor 218 to the fluid conduit 104. As shown in the back view 216, the mass 222 may be rotated around the shaft as indicated by the arrow. In the FIG. 2 embodiment, the motor 218 may be coupled to the filter housing 126 and the vibrations may be transmitted through the filter housing 126 and along any intervening mediums to the fluid conduit 104. In another embodiment, the rotation motor 218 may include a cam shaft element (not shown) that may move the mass 222 back and forth to generate the mechanical energy 206.

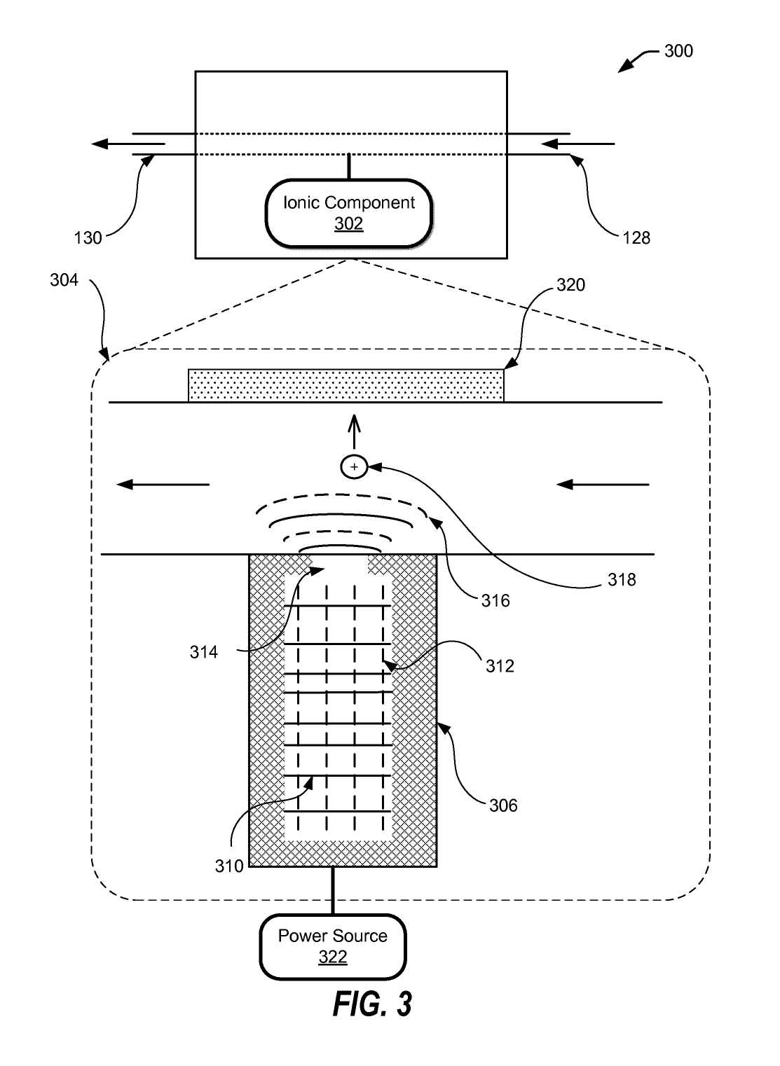

FIG. 3 illustrates a representative embodiment of an electromagnetic filter system 300 that uses electrical energy waves to remove or alter objects in the fluid prior to dispensing the fluid into a process chamber 106. In this embodiment, an ionic component 302 may be used to generate electromagnetic waves that may be tuned to selectively interact with objects with certain electrical characteristics (e.g., charge, ionization energy). The electromagnetic waves may exert a force on the objects with a certain charge or polarity to move or direct the objects 204 in another direction. In this way, certain atoms or molecules may be directed or moved out of the flow path or stream that may be dispensed into the process chamber 106. In another embodiment, objects 204 with the flow may have a certain ionization energy that may be targeted to alter their charge or polarity. The ionization energy may be the amount of energy that may be used to remove an electron from the object 204 and/or change the charge or polarity of the object 204. This may enable another electromagnetic component 302 to direct or move the object 204 in another direction. In another embodiment, the amount of electromagnetic energy may alter the structure or the composition of the object 204 to make the object smaller in size and/or less chemically reactive with other objects 204 in the fluid conduit 104 or on the substrate in the process chamber 106.

The electromagnetic energy may be generated by a power source 322 that may include, but is not limited to, a microwave energy (e.g., 300 MHz-30 GHz) source, radio frequency (RF) energy (e.g., 3 MHz-300 MHz) source, a magnetic field coil, or a combination thereof.

One embodiment of the ionic component 302 is illustrated in the detailed illustration 304. In this embodiment, the ionic component 302 may be a microwave cavity 306 that is powered by a microwave source 308 that may be used to generate electromagnetic energy (e.g., electric wave 310, magnetic wave 312) that may be transmitted through an aperture 314 into the fluid conduit 104. The aperture 314 may include an isolation component (not shown) that allows the electromagnetic energy to pass through and isolate the microwave cavity 306 from the ambient environment and/or the fluid. In another embodiment, the aperture 314 may extend along a longer portion than is shown in FIG. 3. For example, the aperture 314 may extend along the length of the fluid conduit 104 within the filter 102.

The electromagnetic energy 316 may be used to move or direct charged objects 318 out of the fluid flow that will be dispensed into the process chamber 106. In one specific embodiment, the charged objects 318 (e.g., ions) may be directed towards a trap component 320 that may collect or dispose of the charged objects. In another embodiment, the trap component 320 may be another flow path or conduit that directs the charged objects 204 away from the process chamber 106.

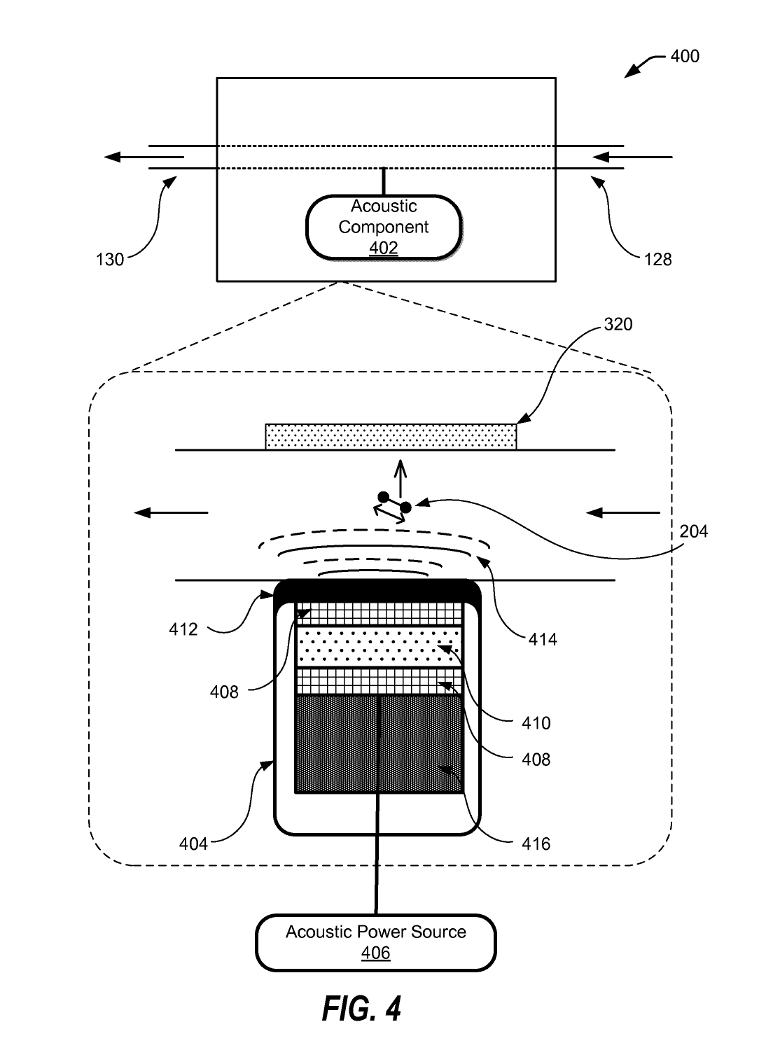

FIG. 4 illustrates a representative embodiment of an acoustic filter system 400 that uses acoustic energy to remove or alter objects in the fluid prior to dispensing the fluid into a process chamber 106. Acoustic energy is a form of mechanical energy, similar to vibration energy described in the description of FIG. 1; however the source of acoustic energy may be generated using different hardware and techniques. For example, the acoustic component 402 may generate acoustic energy using piezoelectric materials instead of rotating masses 222. Piezoelectric materials may be characterized by an electromechanical capability that deforms the crystalline structure of the materials when the material is exposed to an electric field. When the electric field is removed, the crystalline structure returns to its previous position or condition. In this way, vibrations or sound waves may be generated by piezoelectric material when the electric field is pulsed and causes the material to expand and/or contract to apply pressure to a medium (e.g., liquid) to generate a wave within that medium. The waves may be used to move or direct objects out of the flow path or stream that may be delivered to the process chamber 106 or to a trap component that collects the undesirable objects 204 and prevents them from reaching the process chamber 106. The waves may also alter the chemical structure or composition of objects 204 within the fluid conduit 104. The waves may also prevent objects 204 from combining with other objects (not shown) to form larger objects (not shown) or to form a composition that may be chemically undesirable in the fluid conduit 104 or the process chamber 106.

In one embodiment, the acoustic component 402 may include an acoustic insulator 404 that may be coupled to an acoustic power source 406 that may apply an electric field to one or more piezoelectric electrodes 408 that may be in electrical communication with the piezoelectric material 410. In the FIG. 4 embodiment, the piezoelectric material 410 may be disposed between two piezoelectric electrodes 408. When the electric field (not shown) is applied to the piezoelectric material 410 the pressure caused by the contraction/expansion of the piezoelectric material 410 may be applied to the interface component 412 that may be in physical contact with the fluid. The vibrations may be passed into the interface component 412, which in turn, generates acoustic waves 414 within the fluid. The frequency and/or amplitude of the acoustic waves 414 may be tuned to selectively target specific types or classes of objects 204. The backing block 416 may be disposed between the piezoelectric electrodes 408 and the acoustic insulator 404 and may direct the pressure or vibrations from the piezoelectric material 410 towards the interface component 412.

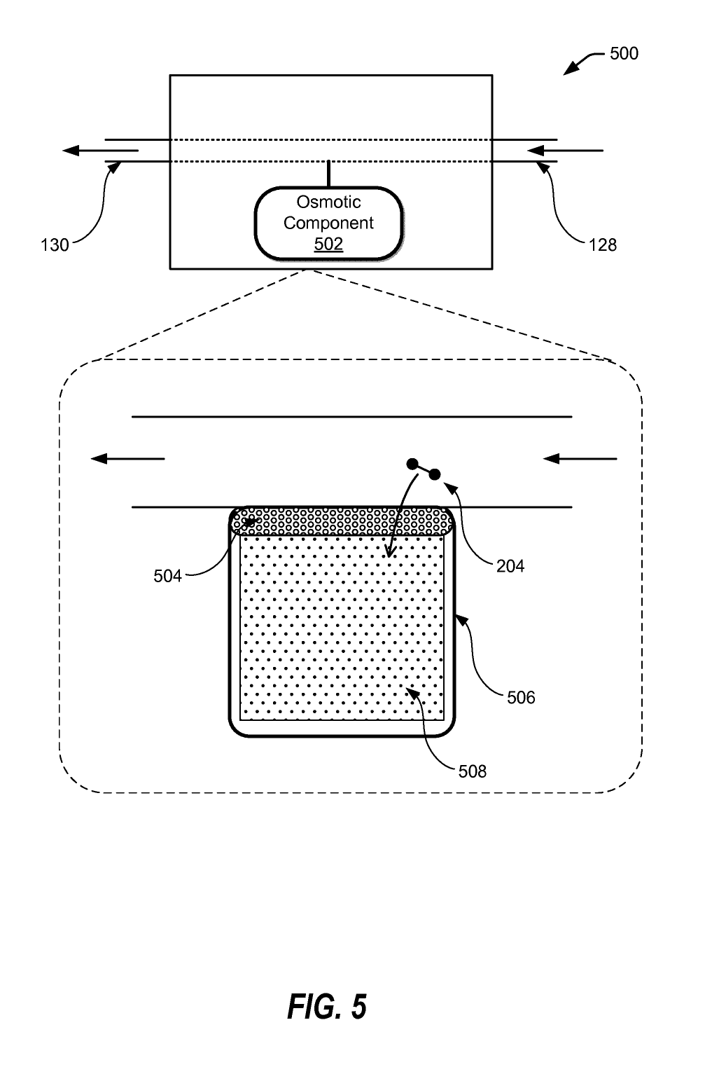

FIG. 5 illustrates a representative embodiment of a chemical potential filter device 500 that uses chemical potential differences to remove or alter objects in the fluid prior to dispensing the fluid into a process chamber 106. Broadly, the chemical potential difference between two liquids across a membrane may be optimized to draw or diffuse elements within one liquid across a semipermeable membrane into the second liquid. The semipermeable membrane may be impermeable to the second liquid and prevents the second liquid from diluting the first liquid. The chemical potential difference or osmotic pressure difference enables the chemical potential filter device 500 to selectively remove objects 204 from the fluid conduit 104 based, at least in part, on the chemical composition of the objects 204.

In one embodiment, the osmotic component 502 may include a membrane 504 that separates the fluid conduit 104 from a chemical container 506 that may be used to extract or remove objects 204 from the fluid conduit 104. The chemical container 506 may include an extraction chemical 508 that may be impermeable to the membrane 504. The chemical potential difference across the membrane 504 may induce diffusion of a portion of the fluid (e.g., objects 204) in the fluid conduit 104 into the chemical container 506. The extraction chemical 508 may be recirculated into the chemical container 506 to maintain a relatively stable chemical potential difference or to tune the chemical potential difference to control the extraction or removal rate of the fluid or objects 204 from the fluid conduit 104.

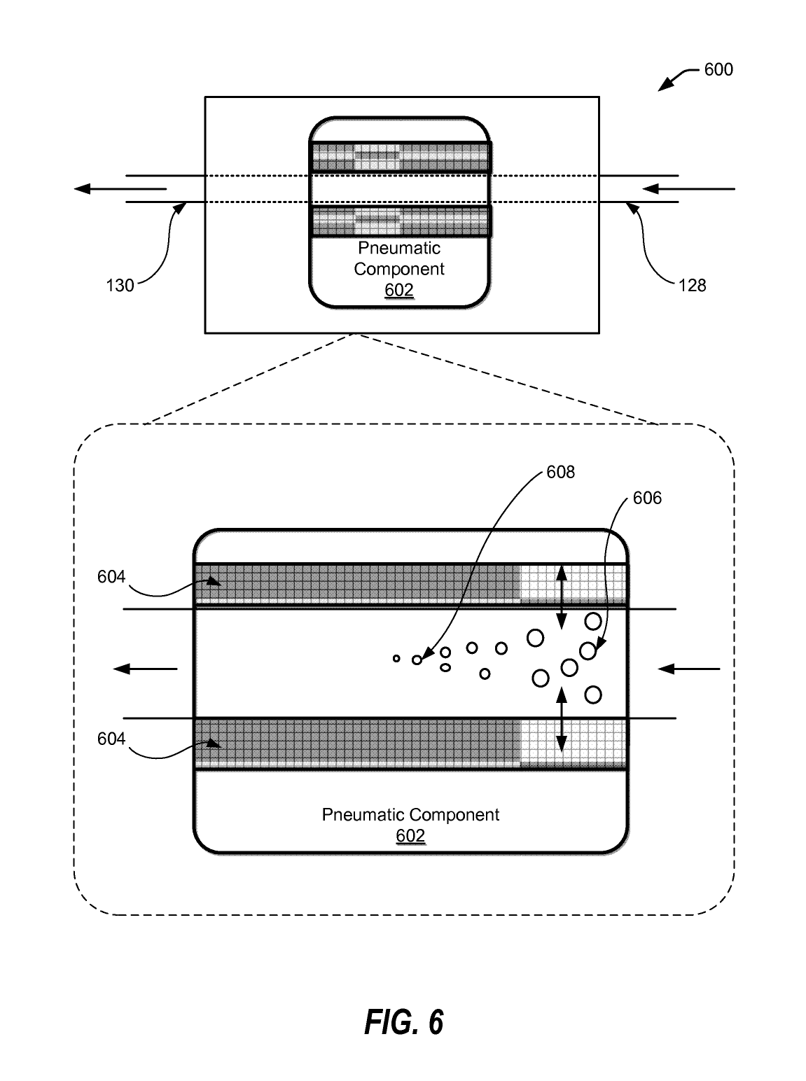

FIG. 6 illustrates a representative embodiment of a pneumatic filter device 600 that uses pressure or vibrations to remove or alter objects 204 in the fluid prior to dispensing the fluid into a process chamber 106. The fluid conduit 104 may include several bends or components that may induce pressure changes or fluctuations of the fluid. Micro-bubbles may be formed in the fluid as a result of the pressure changes. A pneumatic filter device 600 may apply pressure at select points of the fluid conduit to minimize the impact of the pressure changes. In this way, the applied pressure may reduce the density or size of micro-bubbles within the fluid conduit 104. The pneumatic filter device 600 may apply a continuous pressure or be turned on and off by the control module 122 when pressure changes in the line are detected or suspected by the flow module 120. Another approach to reduce defects in the fluid conduit 104 may be to use the pneumatic filter device 600 to generate mechanical energy (e.g., acoustic waves) at selected frequencies and/or amplitudes to the fluid. The mechanical energy may be used to direct or move objects 204 out of the fluid that will be dispensed into the process chamber 106. The objects 204 may also be dissolved into the fluid by the mechanical energy or the objects 204 may be reduced in size (e.g., altering the structure or composition of the object 204) by the mechanical energy.

In the FIG. 6 embodiment, a pneumatic component 602 may include a pressure sleeve that may be wrapped around at least a portion of the fluid conduit 104. In this embodiment, the pressure sleeve is wrapped around the entire fluid conduit 104 and may apply pressure evenly to the fluid conduit 104. The applied pressure may be applied to the fluid to account for pressure changes in the fluid conduit 104 and to dissolve micro-bubbles 606 to smaller micro-bubbles 608 or to dissolve them completely.

In another embodiment, the pneumatic component 602 may a pneumatic actuator (not shown) that may be moved back and forth using gas or fluid pressure to push the actuator in a repetitive motion. The change in momentum may cause the pneumatic component 602 to generate vibrations (not shown) that may be transmitted to the fluid conduit 104. The vibrations may move or direct objects 204 in the fluid out of the fluid flow path that may be delivered to the process chamber 106. The vibrations may also alter the structure or composition of the objects 204 and/or prevent the combination of objects 204 into larger objects 204.

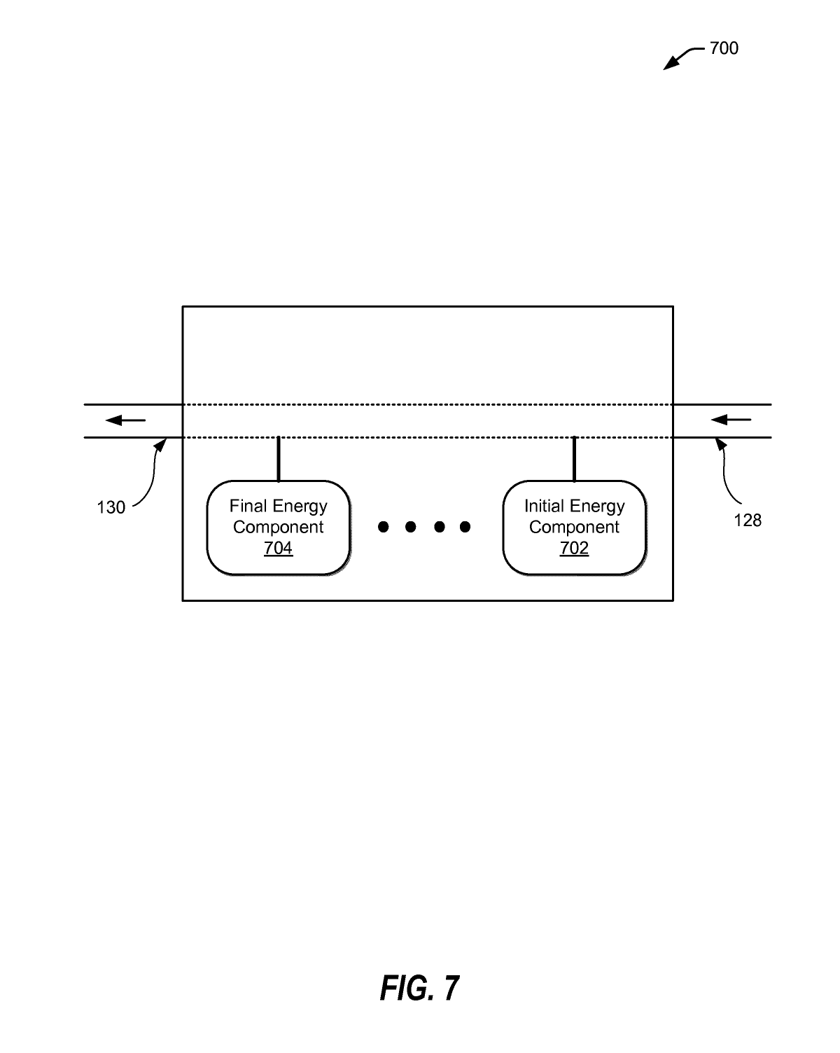

FIG. 7 illustrates a representative embodiment of a filtering system 700 that incorporates two or more or more energy component 110 to remove objects 204 from the fluid prior to dispensing the fluid into a process chamber 106. The fluid conduit 104 may include a plurality of energy component 110 disposed between the liquid source 108 and the process chamber 106. The energy component 110 may be distributed to address several types of problems and be tuned (e.g., energy type, size, frequency, and/or amplitude) and positioned to address defect issues throughout the fluid conduit. The energy components 110 are not limited to point of use applications. In one embodiment, a first group of energy components 110 may be arranged to filter out larger objects 204 to prepare the fluid for a second group of energy components 110 that may filter out another group of objects 204 that may be smaller than the objects 204 filtered out by the first group of energy components 110. In another embodiment, the energy components 110 may be positioned along the fluid conduit 104 that may be known or suspected of generating objects 204. For example, fluid sample lines that may extract a portion of the fluid or a pressure sensor that monitors the fluid pressure or any other portion of the fluid conduit 104 that may cause dead space or bubbles. The energy components 110 may also be used after bends or changes in direction of the fluid conduit 104.

In the FIG. 7 embodiment, the filtering system 700 may include a plurality of energy component 110 distributed along the fluid conduit 104 between the process chamber 106 and the liquid source 108. The initial energy component 702 may include any type filtering technology, including energy components 110, to remove a portion of the objects 204 from the fluid. At some point along the fluid conduit 104 a second energy component 704 may be integrated with the fluid conduit 104 to remove another portion of objects 204 from the fluid. The filtering system 700 may be designed to remove smaller and smaller objects using each of the energy components 110. However, the energy components 110 may also be used to remove the same type of objects 204 at different locations in the fluid conduit 104. For example, a first group (not shown) of energy components 110 may be used to maintain a low distribution of objects throughout the fluid conduit from the liquid source 108 to the process chamber 106. However, a second group of energy components 110 may be used to filter out smaller and smaller objects closer the point of use or dispensing into the process chamber. The filtering system 700 may include several layers of energy components 110 to different types and sizes of objects 204. For example, certain objects based on their size, weight, ionic charge, molecular weight, or a combination thereof may react differently to different types of energy components 110 and/or the settings (e.g., frequency) of the energy component 110. Hence, the scope of the claims is not limited to embodiment illustrated in FIG. 7.

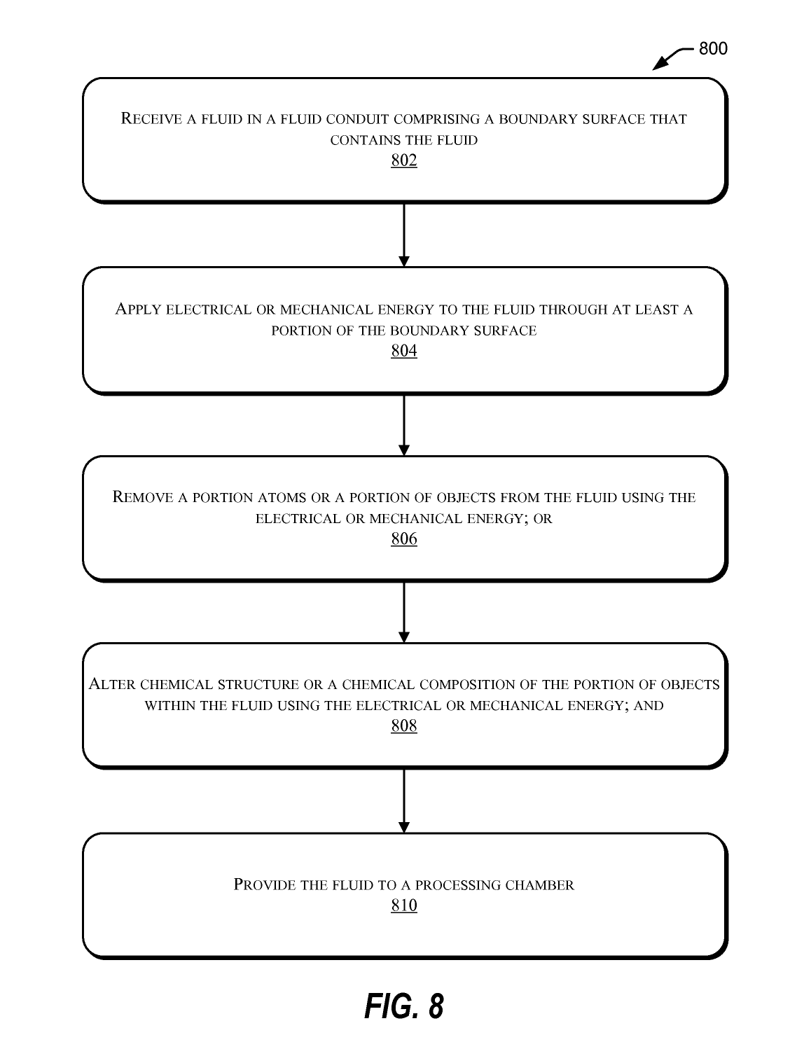

FIG. 8 illustrates a flow diagram 800 for a method of removing objects from a fluid using one or more the energy components. The method may incorporate one or more energy components 110 that may target one or more objects 204 based, at least in part, on the object's size, weight, ionic charge, molecular weight, or a combination thereof. The energy components 110 may be used serially or in parallel to remove, alter, and/or dissolve the objects 204 in the fluid conduit 104. The fluid may include, but are not limited to, liquids dispensed on to substrates used to manufacture semiconductor devices.

At block 802, the filter system 100 may receive a fluid in a fluid conduit 104 that may delivery liquid from a liquid source 108 to a process chamber 106 that may include the substrate. The fluid conduit 104 may include a boundary surface that contains directs the fluid to the process chamber 106. The boundary surface may include a plurality of components along the fluid path. The boundary surface may vary in size and composition along the path, but the boundary surface contains the fluid under pressurized conditions. The boundary surface may include, but is not limited to, portions of the fluid conduit 104 that include filters 102. For example, in some embodiments, the boundary surface may include any surface that is intended to be in physical contact with the fluid along the path between the liquid source 108 and the process chamber 106. The boundary surface may include one or more components that are in fluid communication and contain the fluid within the fluid conduit 104.

At block 804, the energy component 110 may electrical or mechanical energy to the fluid through at least a portion of the boundary surface. The energy may include but, is not limited to, mechanical vibrations, acoustic vibrations, electromagnetic waves, temperature, or combination thereof. The characteristics of the energy may be varied between the same type of energy component 110 or between different types of energy components as described in the description of FIG. 7. The characteristics may include, but are not limited to, frequency, amplitude, temperature, decibel, or combination thereof. The energy may interact with the objects 204 in one or more ways that may prevent or minimize the amount of objects 204 that may be dispensed into the process chamber 106. The objects 204 may include atomic or molecular form of any organic, inorganic, and/or metallic substance that may be in the fluid conduit 104.

At block 806, the energy may be used to remove a portion atoms or a portion of objects 204 (e.g., molecules) from the fluid. The atoms may include monoatomic elements that may or may not be ionized. The energy may target the charge or polarity of the monoatomic elements to move or direct the object 204 away from the flow path. The energy may also target weight and/or size differences between monoatomic elements and/or molecules within the fluid. The energy may be used to selectively direct objects out of the flow path. The energy may also be used to prevent the combination monoatomic elements with each other or with other molecules. Molecular objects 204 may also be similarly targeted using the same techniques.

At block 808, the energy may also alter a chemical structure or a chemical composition of the portion of objects 204 (e.g., molecules). The energy may transform the objects 204 be reducing the size of the molecules that may be dispensed into the process chamber 106. The chemical composition may also be altered to prevent undesired chemical reactions within the fluid conduit 104 or the process chamber 106. In some instances, the objects 204 may be dissolved into the fluid, such that the chemical composition or nature of the objects 204 less distinguishable from other molecules within the fluid or in the same phase (e.g., gas to liquid). For example, minimizing the gas (e.g., micro-bubbles) or dead space found in the liquid. The removal or altering of the objects 204 may be done serially or in parallel within each other. The removal of the objects 204 may include directing the objects 204 to another flow path or conduit that moves the objects away from the process chamber 102 or collects the objects 204 in another filter or trap.

At block 810, the fluid may be dispensed into the process chamber 106 and may be deposited onto the substrate. The fluid may be dispersed across the substrate in a uniform manner and may be chemically react with the substrate or other fluids that may be dispensed on to the substrate.

It should be understood that the foregoing description is only illustrative of the invention. Various alternatives and modifications can be devised by those skilled in the art without departing from the invention. Accordingly, the present invention is intended to embrace all such alternatives, modifications and variances that fall within the scope of the appended claims.

What is claimed is:

1. A fluid treatment device, comprising:
an inlet to receive fluid;
an outlet to provide a treated fluid to a fluid dispenser;
a fluid flow conduit that is in fluid communication with the inlet and the outlet;
a fluid filter component to treat the fluid that passes through the fluid flow conduit, the fluid filter component comprising one or more energy distribution components that provide energy to the fluid.

2. The fluid treatment device of claim 1, wherein the fluid filter component generates one or more forms of energy: acoustic, electromagnetic, thermal, or pneumatic.

3. The fluid treatment device of claim 1, wherein the fluid filter component comprises a mechanical device that provides vibrational energy to the fluid in the fluid flow conduit.

4. The fluid treatment device of claim 3, wherein the mechanical device comprises a vibration device comprising a movement component that can oscillate between different positions or rotate.

5. The fluid treatment device of claim 3, wherein the mechanical device comprises an acoustic device that provides acoustic energy to the fluid in the fluid flow conduit.

6. The fluid treatment device of claim 5, wherein the acoustic energy comprises a frequency of above 350 kHz or below 80 kHz.

7. The fluid treatment device of claim 1, wherein the fluid filter component comprises an electrical device that provides energy to the fluid in the fluid flow conduit.

8. The fluid treatment device of claim 7, wherein the electrical device comprises an electromagnetic wave source that provides electromagnetic energy.

9. The fluid treatment device of claim 7, wherein the electromagnetic energy comprises a frequency of at least 300 MHz.

10. A semiconductor processing system, comprising
a liquid source component for the semiconductor processing system;
a fluid conduit that is in fluid communication with the liquid source component and a semiconductor substrate processing chamber;
a filter in fluid communication with the fluid conduit; and
an energy component that provides electrical or mechanical energy to the fluid conduit.

11. The fluid filtering device of claim 10, wherein the filter comprises a compaction filter in fluid communication with the fluid conduit or an absorption filter in fluid communication with the fluid conduit.

12. The fluid filtering device of claim 10, wherein the energy component generates one or more forms of energy: acoustic, electromagnetic, or thermal.

13. A method for filtering a fluid, comprising:
receiving a fluid in a fluid conduit comprising a boundary surface that contains the fluid;
applying, from an energy component proximate to the fluid conduit, electrical or mechanical energy to the fluid through at least a portion of the boundary surface;
removing a portion atoms or a portion of objects from the fluid using the electrical or mechanical energy; or
altering a chemical structure or a chemical composition of the portion of objects within the fluid using the electrical or mechanical energy; and
providing the fluid to a processing chamber.

14. The method of claim 13, wherein the removing comprises applying an electromagnetic force to the portion of atoms or objects.

15. The method of claim 13, wherein the removing comprises preventing the portions of atoms or objects from reaching the processing chamber.

16. The method of claim 13, wherein the altering of the objects comprises reducing the objects to a smaller size.

17. The method of claim 13, wherein the altering of the objects comprises dissolving the objects within the liquid.

18. The method of claim 13, wherein the objects comprise an organic composition, an inorganic composition, a metallic composition, or a combination thereof.

19. The method of claim 13, wherein the boundary surface comprises one or more components that are in fluid communication and contain the fluid within the fluid conduit.

20. The method of claim 13, wherein the removing and altering of the portions atoms or molecules occur at a similar or same time.
